(19) United States
(12) Patent Application Publication
(10) Pub. No.: US 2009/0086428 A1
(43) Pub. Date: Apr. 2, 2009

(54) DOCKING STATION WITH HYBRID AIR AND LIQUID COOLING OF AN ELECTRONICS RACK

(75) Inventors: Levi A. CAMPBELL, Poughkeepsie, NY (US); Richard C. CHU, Hopewell Junction, NY (US); Michael J. ELLSWORTH, Jr., Lagrangeville, NY (US); Madhusudan K. IYENGAR, Woodstock, NY (US); Robert E. SIMONS, Poughkeepsie, NY (US)

Correspondence Address: HESLIN ROTHENBERG FARLEY & MESITI P.C., 5 COLUMBIA CIRCLE, ALBANY, NY, 12203, US

(73) Assignee: INTERNATIONAL BUSINESS MACHINES CORPORATION, Armonk, NY (US)

(21) Appl. No.: 11/862,346

(22) Filed: Sep. 27, 2007

(51) Int. Cl. H05K 7/20

(52) U.S. Cl. 361/694

(57) ABSTRACT

A docking station is provided for cooling an electronics rack of a data center. The docking station includes an enclosure having at least one wall, a cover coupled to the at least one wall, and a central opening sized to receive the electronics rack therein. The enclosure is separate and freestanding from the electronics rack and surrounds the electronics rack, and facilitates establishing a closed loop airflow path passing through air inlet and outlet sides of the rack and through an air return pathway of the enclosure. The docking station further includes an air-to-liquid heat exchange assembly, disposed within the air return pathway for cooling circulating air passing through the closed loop airflow path, and at least one modular cooling unit, disposed within the enclosure for providing system coolant to the air-to-liquid heat exchange assembly and to at least one electronics subsystem of the electronics rack.

### CROSS-REFERENCE TO RELATED APPLICATIONS

This application contains subject matter which is related to the subject matter of the following applications, each of which is assigned to the same assignee as this application and each of which is hereby incorporated herein by reference in its entirety:
“Docking Station with Closed Loop Airflow Path for Facilitating Cooling of an Electronics Rack”, by Campbell et al., U.S. patent application Ser. No. 11/______, co-filed herewith (Attorney Docket No.: POU920070175US1);
“Method of Assembling a Cooling System for a Multi-Component Electronics System”, by Campbell et al., U.S. patent application Ser. No. 11/539,907, filed Oct. 10, 2006; and
“Liquid-Based Cooling System for Cooling a Multi-Component Electronics System”, by Campbell et al., U.S. patent application Ser. No. 11/539,910, filed Oct. 10, 2006.

### TECHNICAL FIELD

The present invention relates in general to systems and methods for cooling rack-mounted assemblages of individual electronics units, such as rack-mounted computer server units.

### BACKGROUND OF THE INVENTION

The power dissipation of integrated circuit chips, and the modules containing the chips, continues to increase in order to achieve increases in processor performance. This trend poses a cooling challenge at both the module and system level. Increased airflow rates are needed to effectively cool high power modules and to limit the temperature of the air that is exhausted into the computer center.

In many large server applications, processors along with their associated electronics (e.g., memory, disk drives, power supplies, etc.) are packaged in removable drawer configurations stacked within a rack or frame. In other cases, the electronics may be in fixed locations within the rack or frame. Typically, the components are cooled by air moving in parallel airflow paths, usually front-to-back, impelled by one or more air moving devices (e.g., fans or blowers). In some cases it may be possible to handle increased power dissipation within a single drawer by providing greater airflow, through the use of a more powerful air moving device or by increasing the rotational speed (i.e., RPMs) of an existing air moving device. However, this approach is becoming problematic at the rack level in the context of a computer installation (i.e., a data center).

The sensible heat load carried by the air exiting the rack is stressing the ability of the room air-conditioning to effectively handle the load. This is especially true for large installations with “server farms” or large banks of electronics racks close together. In such installations not only will the room air-conditioning be challenged, but the situation may also result in recirculation problems with some fraction of the “hot” air exiting one rack unit being drawn into the air inlet of the same rack or a nearby rack. This recirculating flow is often extremely complex in nature, and can lead to significantly higher rack inlet temperatures than expected. This increase in cooling air temperature may result in components exceeding their allowable operating temperature and in a reduction in long term reliability of the components.

In addition, with the large number of electronics racks in many data center installations, the acoustic noise generated by both the fans in the electronics racks circulating air through the racks, and the fans of the computer room air conditioning units required to cool the data center are rising to unacceptably high levels.

### SUMMARY OF THE INVENTION

The shortcomings of the prior art are overcome and additional advantages are provided through a docking station for facilitating cooling of an electronics rack. The docking station includes an enclosure having at least one wall, a cover coupled to the at least one wall, and a central opening sized to receive an electronics rack therein through an access opening in the at least one wall. The enclosure is separate and freestanding from the electronics rack, and the rack includes at least one electronics drawer, and an air inlet side and an air outlet side. The air inlet and air outlet sides of the electronics rack respectively enable ingress and egress of air. When the electronics rack is operatively positioned within the central opening of the enclosure, the enclosure surrounds the electronics rack and facilitates establishing a closed loop airflow path passing through the air inlet and air outlet sides of the electronics rack and through at least one air return path of the enclosure. The docking station further includes at least one air-to-liquid heat exchange assembly disposed within the air return path of the enclosure for cooling circulating air passing through the closed loop airflow path, and at least one modular cooling unit disposed within the enclosure. The at least one modular cooling unit provides system coolant to the at least one air-to-liquid heat exchange assembly and to at least one electronics subsystem of the electronics rack to be cooled. Each modular cooling unit includes a liquid-to-liquid heat exchanger, a first cooling loop, and a second cooling loop. The first cooling loop receives chilled facility coolant from a source and passes at least a portion thereof through the liquid-to-liquid heat exchanger. The second cooling loop provides cooled system coolant to the at least one air-to-liquid heat exchange assembly and to the at least one electronics subsystem, and expels heat in the liquid-to-liquid heat exchanger from the at least one air-to-liquid heat exchange assembly and from the at least one electronics subsystem to the chilled facility coolant in the first cooling loop.

In a further aspect, a data center is provided which includes at least one electronics rack and at least one docking station. Each electronics rack includes an air inlet side and an air outlet side. The air inlet and air outlet sides respectively enable ingress and egress of air through the electronics rack. Each docking station includes an enclosure, at least one air-to-liquid heat exchange assembly, and at least one modular cooling unit. The enclosure includes at least one wall, a cover coupled to the at least one wall, and a central opening sized to receive a respective electronics rack therein through an access opening in the at least one wall. The enclosure is separate and freestanding from the electronics rack. When the electronics rack is operatively positioned within the central opening of the enclosure, the enclosure surrounds the electronics rack and facilitates establishing a closed loop airflow path therein passing through the air inlet and air outlet sides of the electronics rack and through at least one air return pathway of the enclosure. The at least one air-to-liquid heat exchange assembly is disposed within the at least one air return pathway of the enclosure for cooling air circulating through the closed loop airflow path. The at least one modular cooling unit provides system coolant to the at least one air-to-liquid heat exchange assembly and to at least one electronics subsystem of the electronics rack to be cooled. Each modular cooling unit includes a liquid-to-liquid heat exchanger, a first cooling loop, and a second cooling loop. The first cooling loop receives chilled facility coolant from a source and passes at least a portion thereof through the liquid-to-liquid heat exchanger. The second cooling loop provides cooled system coolant to the at least one air-to-liquid heat exchange assembly and to the at least one electronics subsystem, and expels heat in the liquid-to-liquid heat exchanger from the at least one air-to-liquid heat exchange assembly and from the at least one electronics subsystem to the chilled facility coolant in the first cooling loop.

In a further aspect, a method of cooling an electronics rack is provided. The method includes: providing a docking station for cooling an electronics rack, the docking station comprising: an enclosure comprising at least one wall, a cover coupled to the at least one wall, and a central opening sized to receive the electronics rack therein through an access opening in the at least one wall. The enclosure is separate and freestanding from the electronics rack, and the electronics rack comprising an air inlet side and an air outlet side. The air inlet and air outlet sides respectively enable ingress and egress of air. The docking station further includes at least one air-to-liquid heat exchange assembly disposed within at least one air return pathway of the enclosure for cooling air passing therethrough, and at least one modular cooling unit disposed within the enclosure. Each modular cooling unit includes a liquid-to-liquid heat exchanger, a first cooling loop, and a second cooling loop. Additionally, the method comprises: disposing the electronics rack within the central opening and closing the electronics rack within the enclosure; establishing airflow through the electronics rack employing at least one air moving device, wherein the establishing results in a closed loop airflow pathway being established within the enclosure passing through the air inlet and air outlet sides of the electronics rack and the at least one air return pathway of the enclosure; providing chilled facility coolant from a source to the first cooling loop of each modular cooling unit and passing at least a portion thereof through the liquid-to-liquid heat exchanger, and pumping cooled system coolant through the second cooling loop of each modular cooling unit to the at least one air-to-liquid heat exchange assembly and to at least one electronics subsystem of the electronics rack to be cooled, wherein heat is expelled in the liquid-to-liquid heat exchanger from the at least one air-to-liquid heat exchange assembly and from the at least one electronics subsystem to the chilled facility coolant in the first cooling loop; and employing the at least one air-to-liquid heat exchange assembly to cool air circulating within the enclosure through the closed loop airflow path, and employing the at least one modular cooling unit to cool the at least one air-to-liquid heat exchange assembly and to cool the at least one electronics subsystem of the at least one electronics rack.

Further, additional features and advantages are realized through the techniques of the present invention. Other embodiments and aspects of the invention are described in detail herein and are considered a part of the claimed invention.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1A depicts one embodiment of a conventional raised floor layout of an air cooled data center;

FIG. 1B depicts one embodiment of a conventional non-raised floor layout of an air cooled data center, wherein overhead air ducts and diffusers are employed in distributing cooled airflow to the electronics racks;

FIG. 2 depicts one problem addressed by the present invention, showing re-circulation airflow patterns in one implementation of a raised floor layout of an air cooled data center;

FIG. 3A is a cross-sectional plan view of one embodiment of an electronics rack using attached liquid-to-air heat exchangers to enhance cooling of air passing through the electronics rack;

FIG. 3B is a cross-sectional plan view of another embodiment of an electronics rack using an attached liquid-to-air heat exchanger to enhance cooling of air passing though the electronics rack;

FIG. 4 is a top plan view of one embodiment of a docking station with hybrid air and liquid cooling of an electronics rack operatively disposed therein (shown with the top cover removed), in accordance with an aspect of the present invention;

FIG. 5 depicts a front elevational view of the docking station of FIG. 4 (shown with the front access doors removed), in accordance with an aspect of the present invention;

FIG. 6 is a schematic in one embodiment of an electronics subsystem of an electronics rack, wherein an electronics module is liquid-cooled by system coolant provided by one or more modular cooling units disposed within the docking station, in accordance with an aspect of the present invention;

FIG. 7 is a schematic of one embodiment of a modular cooling unit to be disposed within a docking station, in accordance with an aspect of the present invention;

FIG. 8 is a plan view of one embodiment of an electronics subsystem layout illustrating an air and liquid cooling system for cooling components of the electronics subsystem, in accordance with an aspect of the present invention;

FIG. 9 depicts one detailed embodiment of a partially assembled electronics subsystem layout, wherein the electronics subsystem includes eight heat-generating electronic components to be actively cooled, each having a respective liquid-cooled cold plate of a liquid-based cooling system coupled thereto, in accordance with an aspect of the present invention;

FIG. 10 is a top plan view of the docking station embodiment of FIGS. 4 & 5, illustrating the bifurcated, closed loop airflow path established within the enclosure (and again shown with the cover removed), in accordance with an aspect of the present invention; and

FIG. 11 is a side elevational view of the docking station of FIGS. 5, 6 & 10, illustrating relative sizing of the modular cooling unit(s) and the air-to-liquid head assembly relative to the docking station and electronics rack disposed therein (shown with the sidewall of the docking station removed), in accordance with an aspect of the present invention.

### DETAILED DESCRIPTION OF THE INVENTION

As used herein, the terms “electronics rack”, “rack-mounted electronic equipment”, and “rack unit” are used interchangeably, and unless otherwise specified include any housing, frame, rack, compartment, blade server system, etc., having one or more heat generating components of a computer system or electronics system, and may be, for example, a stand alone computer processor having high, mid or low end processing capability. In one embodiment, an electronics rack may comprise multiple electronics subsystems or drawers, each having one or more heat generating components disposed therein requiring cooling. “Electronics subsystem” refers to any sub-housing, blade, book, drawer, node, compartment, etc., having one or more heat generating electronic components disposed therein. Each electronics subsystem of an electronics rack may be movable or fixed relative to the electronics rack, with the rack-mounted electronics drawers and blades of a blade center system being two examples of subsystems of an electronics rack to be cooled.

“Electronic component” refers to any heat generating electronic component of, for example, a computer system or other electronics unit requiring cooling. By way of example, an electronic component may comprise one or more integrated circuit dies and/or other electronic devices to be cooled, including one or more processor dies, memory dies and memory support dies. As a further example, the electronic component may comprise one or more bare dies or one or more packaged dies disposed on a common carrier. As used herein, “primary heat generating component” refers to a primary heat generating electronic component within an electronics subsystem, while “secondary heat generating component” refers to an electronic component of the electronics subsystem generating less heat than the primary heat generating component to be cooled. “Primary heat generating die” refers, for example, to a primary heat generating die or chip within a heat generating electronic component comprising primary and secondary heat generating dies (with a processor die being one example). “Secondary heat generating die” refers to a die of a multi-die electronic component generating less heat than the primary heat generating die thereof (with memory dies and memory support dies being examples of secondary dies to be cooled). As one example, a heat generating electronic component could comprise multiple primary heat generating bare dies and multiple secondary heat generating dies on a common carrier. Further, unless otherwise specified herein, the term “liquid-cooled cold plate” refers to any conventional thermally conductive structure having a plurality of channels or passageways formed therein for flowing of liquid coolant therethrough. In addition, “metallurgically bonded” refers generally herein to two components being welded, brazed or soldered together by any means.

As used herein, “air-to-liquid heat exchange assembly” means any heat exchange mechanism characterized as described herein through which liquid coolant can circulate; and includes, one or more discrete air-to-liquid heat exchangers coupled either in series or in parallel. An air-to-liquid heat exchanger may comprise, for example, one or more coolant flow paths, formed of thermally conductive tubing (such as copper or other tubing) in thermal or mechanical contact with a plurality of air-cooled cooling fins. Size, configuration and construction of the air-to-liquid heat exchange assembly and/or air-to-liquid heat exchanger thereof can vary without departing from the scope of the invention disclosed herein. A “liquid-to-liquid heat exchanger” may comprise, for example, two or more coolant flow paths, formed of thermally conductive tubing (such as copper or other tubing) in thermal or mechanical contact with each other. Size, configuration and construction of the liquid-to-liquid heat exchanger can vary without departing from the scope of the invention disclosed herein. Further, “data center” refers to a computer installation containing one or more electronics racks to be cooled. As a specific example, a data center may include one or more rows of rack-mounted computing units, such as server units.

One example of facility coolant and system coolant is water. However, the concepts disclosed herein are readily adapted to use with other types of coolant on the facility side and/or on the system side. For example, one or more of the coolants may comprise a brine, a fluorocarbon liquid, a liquid metal, or other similar coolant, or refrigerant, while still maintaining the advantages and unique features of the present invention.

Reference is made below to the drawings, which are not drawn to scale for reasons of understanding, wherein the same reference numbers used throughout different figures designate the same or similar components.

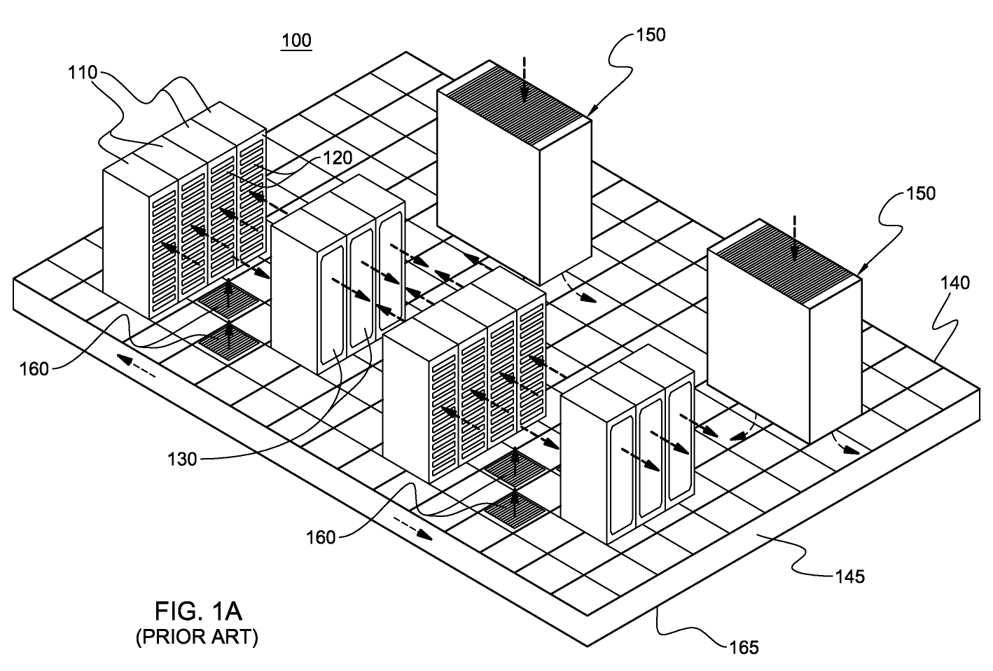

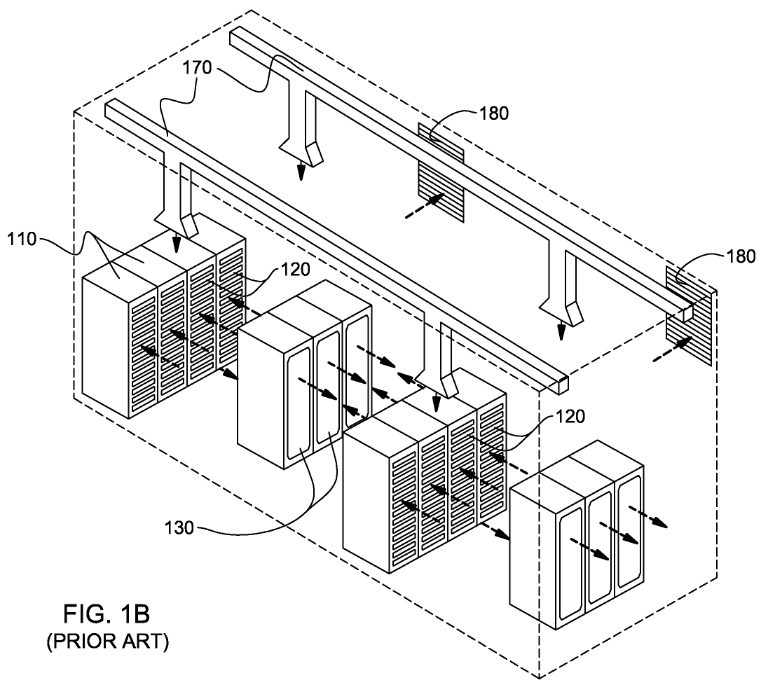

FIG. 1A depicts a raised floor layout of an air cooled data center 100 typical in the prior art, wherein multiple electronics racks 110 are disposed in one or more rows. A data center such as depicted in FIG. 1A may house several hundred, or even several thousand microprocessors. In the arrangement illustrated, chilled air enters the computer room via perforated floor tiles 160 from a supply air plenum 145 defined between the raised floor 140 and a base or sub-floor 165 of the room. Cooled air is taken in through louvered covers at air inlet sides 120 of the electronics racks and expelled through the back (i.e., air outlet sides 130) of the electronics racks. Each electronics rack 110 may have one or more air moving devices (e.g., fans or blowers) to provide forced inlet-to-outlet airflow to cool the electronic components within the drawer(s) of the rack. The supply air plenum 145 provides conditioned and cooled air to the air-inlet sides of the electronics racks via perforated floor tiles 160 disposed in a “cold” aisle of the computer installation. The conditioned and cooled air is supplied to plenum 145 by one or more air conditioning units 150, also disposed within the data center 100. Room air is taken into each air conditioning unit 150 near an upper portion thereof. This room air comprises in part exhausted air from the “hot” aisles of the computer installation defined by opposing air outlet sides 130 of the electronics racks 110.

FIG. 1B depicts an alternate data center configuration wherein multiple electronics racks 110 disposed in rows are cooled via conditioned and cooled air entering the room from overhead ducts and diffusers 170. Air exits the room via vents 180 that may be placed at different locations within the room. The ducts and diffusers 170 are disposed to align to the cold aisle of the multiple rows and provide cooled air to the air inlet sides 120 of the electronics racks. Air moving devices within the racks move the cooled air through the racks from inlet side to outlet side to cool the heat generating components therein. Heated air is again exhausted at the hot aisles of the racks through the air outlet sides 130 of electronics racks 110. In one embodiment, returns 180 can be aligned to the hot aisles defined by the opposing air exhaust sides 130 of the electronics racks.

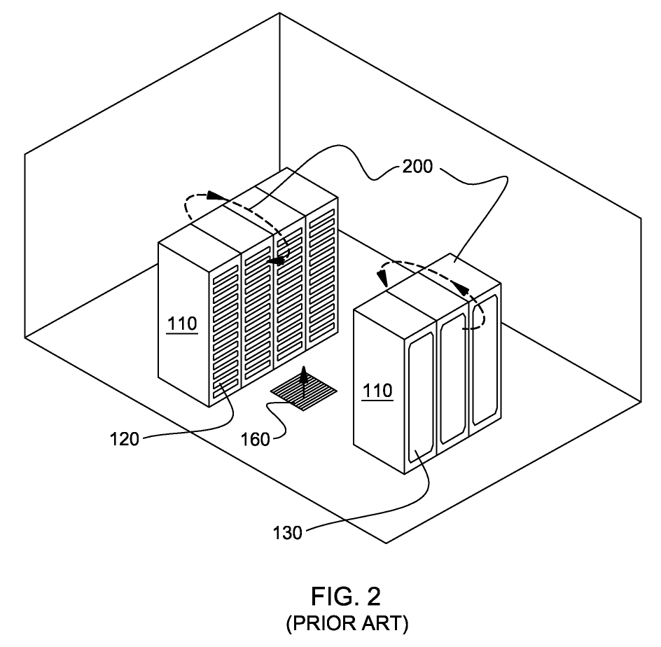

Due to the ever increasing airflow requirements through electronics racks, and limits of air distribution within the typical data center installation, re-circulation problems within the room may occur. This is shown in FIG. 2 for a raised floor layout, wherein hot air re-circulation 200 occurs from the air outlet sides 130 of the electronics racks 110 back to the cold air aisle defined by the opposing air inlet sides 120 of the electronics rack. This re-circulation can occur because the conditioned air supplied through tiles 160 is typically only a fraction of the airflow rate forced through the electronics racks by the air moving devices disposed therein. This can be due, for example, to limitations on the tile sizes (or diffuser flow rates). The remaining fraction of the supply of inlet side air is often made up by ambient room air through re-circulation 200. This recirculating flow is often very complex in nature, and can lead to significantly higher rack unit inlet temperatures than desired.

The re-circulation of hot exhaust air from the hot aisle of the computer room installation to the cold aisle can be detrimental to the performance and reliability of the computer system(s) or electronic system(s) within the racks. Data center equipment is typically designed to operate with rack air inlet temperatures in the 18-35° C. range. For a raised floor layout such as depicted in FIG. 1A, however, temperatures can range from 15-20° C. at the lower portion of the rack, close to the cooled air input floor vents, to as much as 45-50° C. at the upper portion of the electronics rack, where the hot air can form a self-sustaining re-circulation loop. Since the allowable rack heat load is limited by the rack inlet air temperature at the “hot” part, this temperature distribution correlates to an inefficient utilization of available chilled air. Also, computer installation equipment almost always represents a high capital investment to the customer. Thus, it is of significant importance, from a product reliability and performance view point, and from a customer satisfaction and business perspective, to limit the temperature of the inlet air to the rack unit to be substantially uniform. The efficient cooling of such computer and electronic systems, and the amelioration of localized hot air inlet temperatures to one or more rack units due to re-circulation of air currents, are addressed by the apparatuses and methods disclosed herein, as is reducing acoustic noise within the data center.

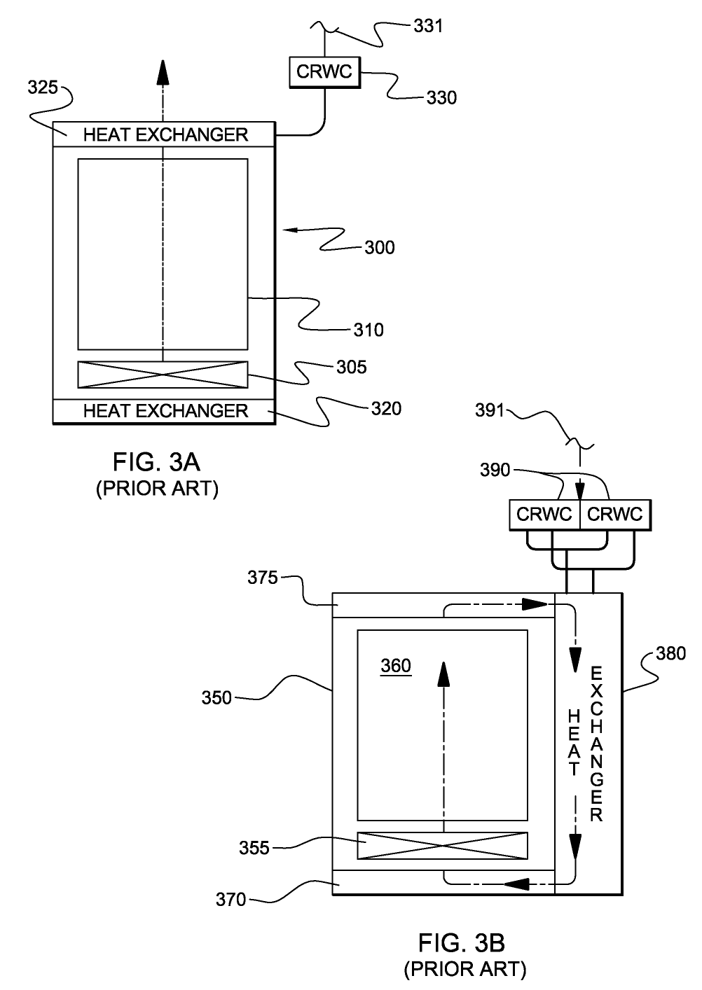

FIGS. 3A and 3B depict prior rack level water cooled solutions which utilize chilled facility water to remove heat from the computer installation room, thereby transferring the cooling burden from the air-conditioning units to the building chilled water coolers. The embodiment of FIG. 3A is described in detail in commonly assigned U.S. Pat. No. 6,819,563, while the embodiment of FIG. 3B is described in detail in commonly assigned U.S. Pat. No. 6,775,137, both of which are incorporated herein by reference in their entirety. Briefly summarized, both embodiments utilize a computer room water conditioning unit 330 (FIG. 3A), 390 (FIG. 3B) (fed with facility chilled water 331 (FIG. 3A), 391 (FIG. 3B)), which circulates chilled coolant through one or more heat exchangers coupled to individual electronics racks 300, 350 within the computer room.

In the embodiment of FIG. 3A, electronics rack 300 has an inlet heat exchanger 320 and/or an outlet heat exchanger 325 attached to the rack. Airflow across one or more electronics drawers 310 is forced via one or more air moving devices 305. Each heat exchanger 320, 325 covers the complete airflow paths from front to back, with the air intake being chilled by heat exchanger 320, and the heated exhaust chilled by heat exchanger 325. Thus, the inlet-to-outlet airflow paths through the rack unit each pass through the same sequence of heat exchangers.

In FIG. 3B, rack unit 350 again includes one or more air moving devices 355 for moving airflow from an air inlet side to an air outlet side across one or more drawer units 360 containing the heat generating components. In this embodiment, a front cover 370 attached to the rack covers the air inlet side, a back cover 375 attached to the rack covers the air outlet side thereof, and a side car attached to the rack includes a heat exchanger 380 for cooling of the air circulating through the rack unit. Further, in this embodiment, multiple computer room water conditioning (CRWC) units 390 receive building or facility chilled water 391, which is then used to cool coolant circulating through heat exchanger 380. The rack unit in this example is assumed to comprise a substantially enclosed housing wherein the same air circulates through the housing and passes across the heat exchanger 380.

One drawback to the rack level water cooled solutions depicted in FIGS. 3A & 3B is the assembly required to attach the front heat exchanger, back heat exchanger, front door, back door and/or side car (depending on the configuration) to the electronics rack either by the manufacturer or the data center operator. The solutions depicted in FIGS. 3A & 3B need to be customized to a particular manufacturer's electronics rack. Further, as heat loads continue to increase to 100 kW and beyond, the air-to-liquid heat exchangers required to cool the racks will be very large. Therefore, it may be impractical to have such large and heavy structures attached to the electronics racks themselves.

Advantageously, the invention disclosed herein solves, in one aspect, the problems noted above by providing a modular docking station separate and freestanding from the electronics rack, which includes a hybrid air and liquid cooling facility. The hybrid air and liquid cooling facility includes one or more modular cooling units and an air-to-liquid heat exchange assembly, both disposed within the docking station. Further, the docking station facilitates defining a closed loop airflow path passing through the electronics rack and heat exchange assembly. When operational, hot air exiting the electronics rack within the sealed enclosure of the docking station passes through the air-to-liquid heat exchange assembly and is cooled before returning to an air inlet side of the electronics rack. Containment of the airflow within the docking station reduces the level of acoustic emissions to the outside data center room. Further, one or more modular cooling units within the docking station provide cooled system coolant to the air-to-liquid heat exchange assembly and to one or more cooling systems cooling at least one electronics subsystem of the electronics rack. The cooling systems employ liquid-cooled cold plates configured to couple to respective heat-generating electronics components of the electronics subsystem. Together, the hybrid air and liquid cooling provided by the docking station extracts substantially 100% of the electronics rack heat load via the liquid-to-liquid heat exchanger(s) within the one or more modular cooling units of the docking station. This cooling approach dramatically reduces the number of noisy, less efficient computer room air-conditioning units required within the data center.

Advantageously, the docking station disclosed herein facilities cooling of both air-cooled components (e.g., memory modules) and components cooled with liquid-cooled cold plates (e.g., processors) disposed within the electronics subsystems of the electronics rack. The docking station provides cooled system coolant to cool both the liquid-cooled cold plates within the electronics rack and the at least one air-to-liquid heat exchange assembly disposed within the docking station. The cooled system coolant is provided by one or more modular cooling units within the docking station enclosure, which also allow for temperature control of the coolant within the docking station, thereby eliminating the need for an external coolant distribution unit and providing enhanced control over and customization of cooling provided to the electronics racks within a data center.

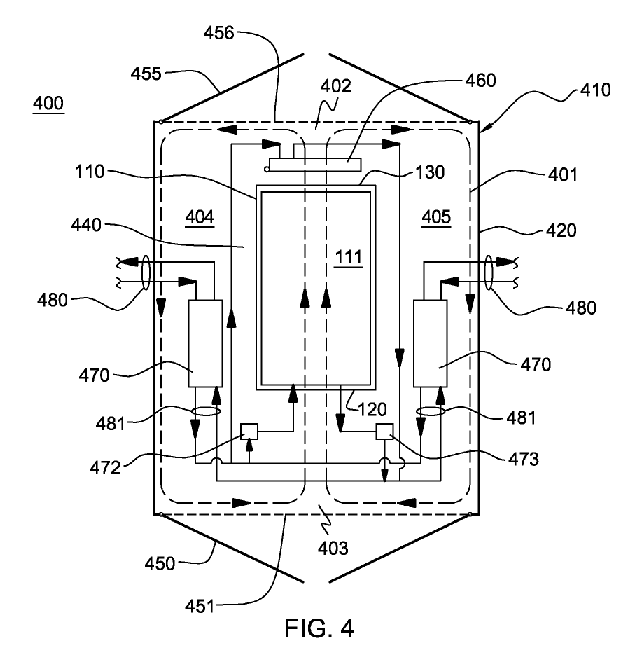

One embodiment of a docking station 400, in accordance with the invention disclosed herein, is depicted in FIG. 4. In this embodiment, docking station 400 comprises an enclosure 410 with at least one outer wall 420 and a top cover (not shown) connected to the at least one outer wall 420. A central opening 440 is provided within docking station 400. The central opening is sized to receive an electronics rack 110 therein. Electronics rack 110 includes an electronics subsystem 111, such as a processor node. Spaced, opposing outer side walls 420 of enclosure 410 facilitate defining of central opening 440. In this embodiment, central opening 440 is sized to receive electronics rack 110, as well as two modular cooling units 470 and an air-to-liquid heat exchange assembly 460. Electronics rack 110 comprises, for example, one or more heat-generating components disposed therein requiring cooling, and includes an air inlet side 120 and an air outlet side 130, with the air inlet and air outlet sides respectively enabling ingress and egress of air through the electronics rack 110, propelled, for example, via one or more fans (not shown) disposed within the rack unit.

When operatively positioned within the docking station, the fans within the electronics rack draw air into the air inlet side of the rack and exhaust air out the air outlet side of the rack through air-to-liquid heat exchanger assembly 460 mounted within the docking station adjacent to, for example, the air outlet side of the rack. Cooled air exiting the air-to-liquid heat exchange assembly is then returned to the air inlet side of the electronics rack.

Advantageously, outer wall 420 and the cover of enclosure 410 encircle and seal or close electronics rack 110 within docking station 400 once the rack is operatively positioned within central opening 440, as illustrated in FIG. 4. This allows a closed loop airflow path 401 to be established within the docking station passing through electronics rack 110, with air flow passing from air inlet side 120 of electronics rack 110 to air outlet side 130. By appropriately sizing the enclosure, closed loop airflow path 401 bifurcates in a rear air return pathway 402 for return via one of two side air return pathways 404, 405 and front air return pathway 403, as shown in FIG. 4.

Electronics rack 110 is slid or rolled into position within central opening 440 through a first access opening 451 in the at least one wall 420 exposed, for example, by pivoting open hinged front access doors 450. Similarly, back access doors 455 are hingedly mounted within docking station 400 to allow access through a back access opening 456 to, for example, air-to-liquid heat exchange assembly 460 and/or the air outlet side 130 of electronics rack 110.

In the embodiment of FIG. 4, cooled system coolant (e.g., water) is supplied by two modular cooling units 470. Modular cooling units 470 are connected in parallel to a coolant inlet of air-to-liquid heat exchange assembly 460 and to a shared system coolant supply manifold 472 providing cooled system coolant to one or more cooling systems within one or more electronics subsystems within the electronics rack. Similarly, system coolant is received in parallel at the modular cooling units 470 from the at least one air-to-liquid heat exchange assembly 460 and from the cooling system(s) cooling the one or more electronics subsystems of the electronics rack via a shared system coolant return manifold 473.

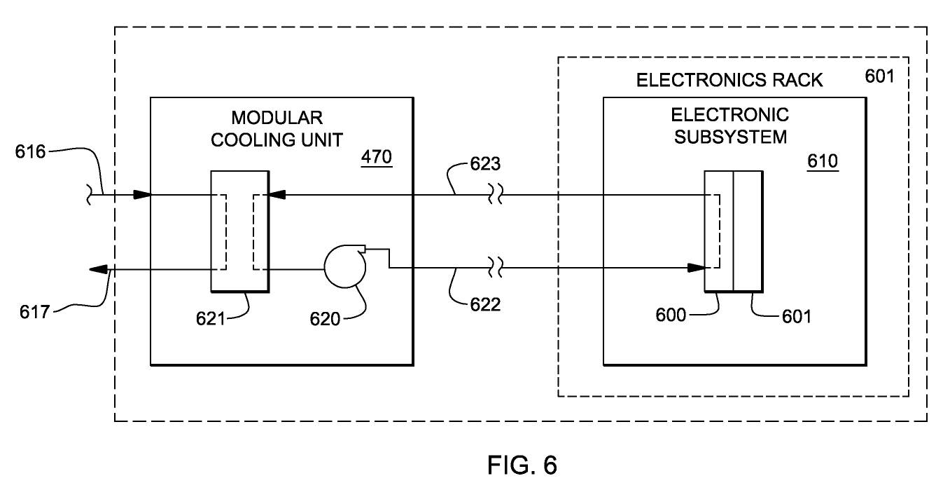

More particularly, within each modular cooling unit 470, a liquid-to-liquid heat exchanger is provided, as well as a first cooling loop and a second cooling loop. The first cooling loop 480 receives chilled facility coolant from a source (not shown), and passes at least a portion thereof through the liquid-to-liquid heat exchanger, as explained further below in connection with FIGS. 6 & 7. The second cooling loops 481 provide cooled system coolant to the at least one air-to-liquid heat exchange assembly 460 and to the shared system coolant supply manifold 472, and expels heat in the liquid-to-liquid heat exchanger from the at least one air-to-liquid heat exchange assembly 460 and from at least one electronics subsystem of the electronics rack, via the shared system coolant return manifold 473, to the chilled facility coolant in the first cooling loops 480.

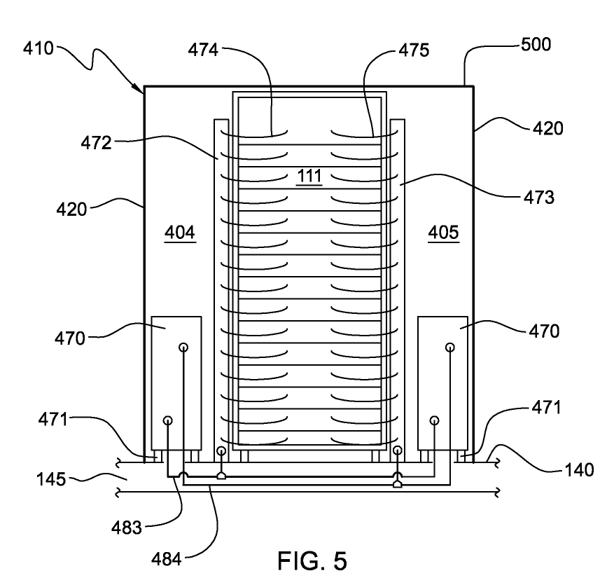

FIG. 5 depicts a further detailed embodiment of the first cooling loops of modular cooling units 470. In this raised floor data center embodiment, the docking station is disposed, for example, in a fixed position on a raised floor 140, and modular cooling units 470 are positioned in the side air return pathways 404, 405 defined between outer side walls 420 of enclosure 410 and opposing sides of the electronics rack. In this embodiment, each modular cooling unit is shown to include a system coolant supply hose 483 and a system coolant return hose 484, which extend below raised floor 140 and couple to shared system coolant supply manifold 472 and shared system coolant return manifold 473, respectively (in addition to coupling to the at least one air-to-liquid heat exchange assembly, as illustrated in FIG. 4). Shared system coolant supply manifold 472 provides system coolant to the cooling systems, more particularly, to liquid-cooled cold plates thereof, via flexible hose connections 474, 475 between manifolds 472, 473, respectively, and the individual electronics subsystems within the electronics rack. Quick connect couplings may be employed at the interface between flexible hoses 474, 475 and the individual electronics subsystems. By way of example, these quick connect couplings may comprise various types of commercially available couplings, such as those available Colder Products Company, of St. Paul, Minn., USA, or Parker Hannifin, of Cleveland, Ohio, USA.

As shown in FIGS. 4 & 5, the shared coolant system supply and return manifolds are mounted external to the electronics frame and are part of the docking station itself. The modular cooling units are also part of the docking station, and in one embodiment, are supported on rails, guides or wheels 471, so that the modular cooling units may be readily rolled into or out of the docking station enclosure for installation, repair or replacement. In the embodiment of FIG. 5, coolant supply and return lines connecting the modular cooling units, system supply/return manifolds, and air-to-liquid heat exchange assembly are routed under raised floor 140 so as not to interfere with free movement of the rack unit into or out of the docking station.

FIG. 5 also illustrates one example of relative sizing of the modular cooling units 470 relative to the side air return pathways 404, 405 defined within the docking station. Further, FIG. 5 illustrates that space is provided between the modular cooling units and the outer wall of the docking station, as well as between the modular cooling units and the shared supply and return manifolds. This ensures that re-circulating air passing through the side air return pathways can flow around the modular cooling units to reach the air inlet side of the electronics rack when the closed loop airflow path is established within the docking station.

FIG. 6 schematically illustrates operation of the liquid cooling facility of FIGS. 4 & 5, wherein a liquid cooled cold plate 600 is shown coupled to an electronics module 601 of electronics drawer 610 within the electronics rack. Heat is removed from electronics module 601 via the system coolant circulated via pump 620 through cold plate 600 within the system coolant loop defined by liquid-to-liquid heat exchanger 621 of coolant distribution unit 470, lines 622, 623 and cold plate 600. The system coolant loop and modular cooling unit are designed to provide coolant of a controlled temperature and pressure, as well as controlled chemistry and cleanliness to the electronics module(s). Furthermore, the system coolant is physically separate from the less controlled facility coolant in lines 616, 617 to which heat is ultimately transferred.

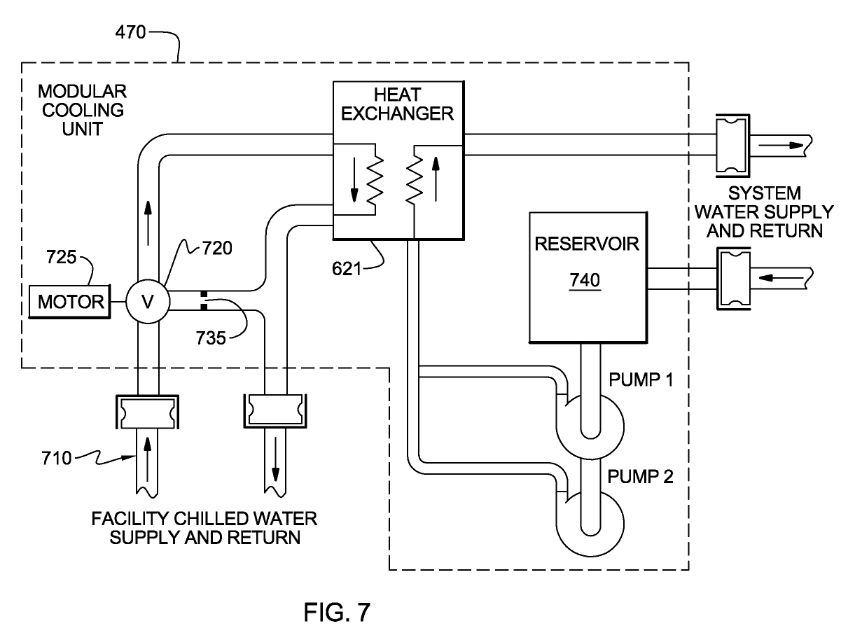

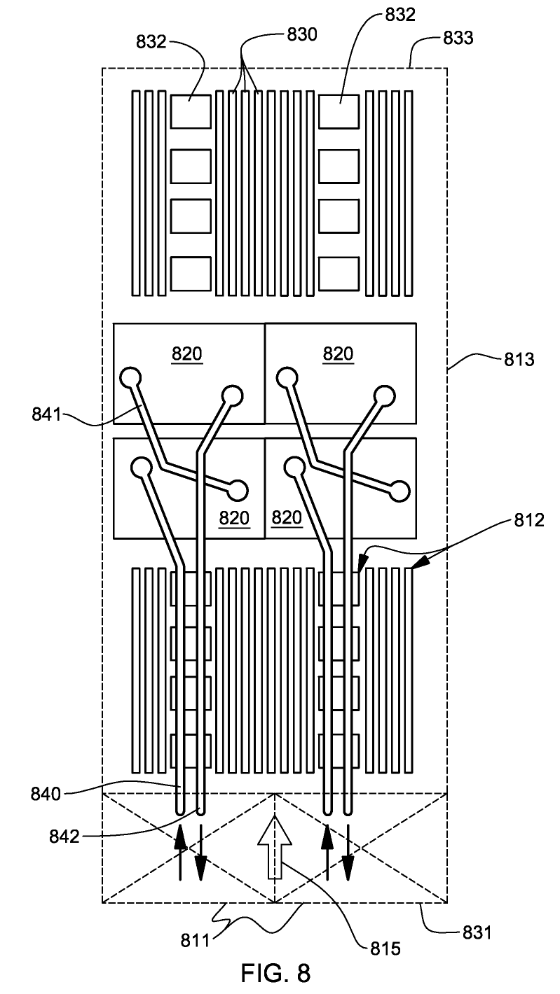

FIG. 7 depicts a more detailed embodiment of a modular cooling unit 470, in accordance with an aspect of the present invention. As shown in FIG. 7, modular cooling unit 470 includes a first cooling loop wherein building chilled, facility coolant is supplied 710 and passes through a control valve 720 driven by a motor 725. Valve 720 determines an amount of facility coolant to be passed through a heat exchanger 621, with a portion of the facility coolant possibly being returned directly via a bypass orifice 735. The modular cooling unit further includes a second cooling loop with a reservoir tank 740 from which system coolant is pumped, either by pump 1 or pump 2, into the heat exchanger 621 for conditioning and output thereof as cooled system coolant to the electronics rack to be cooled within the docking station. The cooled system coolant is supplied to one or more cooling systems within one or more electronics drawers of the electronics rack via the shared supply and return manifolds.

FIG. 8 depicts one embodiment of an electronics drawer 813 component layout wherein one or more air moving devices 811 provide forced air flow 815 to cool multiple components 812 within electronics drawer or subsystem 813. Cool air is taken in through a front 831 and exhausted out a back 833 of the drawer. The multiple components to be cooled include multiple processor modules to which liquid-cooled cold plates 820 (of a liquid-based cooling system) are coupled, as well as multiple arrays of memory modules 830 (e.g., dual in-line memory modules (DIMMs)) and multiple rows of memory support modules 832 (e.g., DIMM control modules) to which air-cooled heat sinks are coupled. In the embodiment illustrated, memory modules 830 and the memory support modules 832 are partially arrayed near front 831 of electronics drawer 813, and partially arrayed near back 833 of electronics drawer 813. Also, in the embodiment of FIG. 8, memory modules 830 and the memory support modules 832 are cooled by air flow 815 across the electronics drawer.

The illustrated liquid-based cooling system further includes multiple coolant-carrying tubes connected to and in fluid communication with liquid-cooled cold plates 820. The coolant-carrying tubes comprise sets of coolant-carrying tubes, with each set including (for example) a coolant supply tube 840, a bridge tube 841 and a coolant return tube 842. In this example, each set of tubes provides liquid coolant to a series-connected pair of cold plates 820 (coupled to a pair of processor modules). Coolant flows into a first cold plate of each pair via the coolant supply tube 840 and from the first cold plate to a second cold plate of the pair via bridge tube or line 841, which may or may not be thermally conductive. From the second cold plate of the pair, coolant is returned through the respective coolant return tube 842.

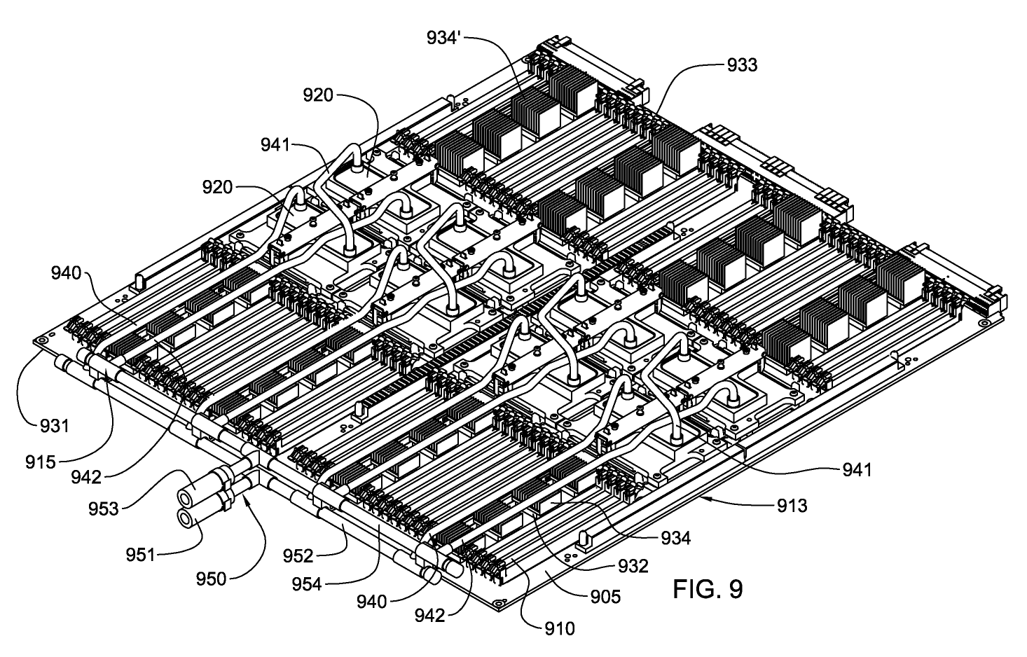

FIG. 9 depicts in greater detail an alternate electronics drawer layout comprising eight processor modules, each having a respective liquid-cooled cold plate of a liquid-based cooling system coupled thereto. The liquid-based cooling system is shown to further include associated coolant-carrying tubes for facilitating passage of liquid coolant through the liquid-cooled cold plates and a header subassembly to facilitate distribution of liquid coolant to and return of liquid coolant from the liquid-cooled cold plates. By way of specific example, the liquid coolant passing through the liquid-based cooling subsystem is chilled water.

As noted, various liquid coolants significantly outperform air in the task of removing heat from heat generating electronic components of an electronics system, and thereby more effectively maintain the components at a desirable temperature for enhanced reliability and peak performance. As liquid-based cooling systems are designed and deployed, it is advantageous to architect systems which maximize reliability and minimize the potential for leaks while meeting all other mechanical, electrical and chemical requirements of a given electronics system implementation. These more robust cooling systems have unique problems in their assembly and implementation. For example, one assembly solution is to utilize multiple fittings within the electronics system, and use flexible plastic or rubber tubing to connect headers, cold plates, pumps and other components. However, such a solution may not meet a given customer's specifications and need for reliability.

Thus, presented herein in one aspect is a robust and reliable liquid-based cooling system specially preconfigured and prefabricated as a monolithic structure for positioning within a particular electronics drawer.

FIG. 9 is an isometric view of one embodiment of an electronics drawer and monolithic cooling system, in accordance with an aspect of the present invention. The depicted planar server assembly includes a multi-layer printed circuit board to which memory DIMM sockets and various electronic components to be cooled are attached both physically and electrically. In the cooling system depicted, a supply header is provided to distribute liquid coolant from a single inlet to multiple parallel coolant flow paths and a return header collects exhausted coolant from the multiple parallel coolant flow paths into a single outlet. Each parallel coolant flow path includes one or more cold plates in series flow arrangement to cool one or more electronic components to which the cold plates are mechanically and thermally coupled. The number of parallel paths and the number of series-connected liquid-cooled cold plates depends, for example on the desired device temperature, available coolant temperature and coolant flow rate, and the total heat load being dissipated from each electronic component.

More particularly, FIG. 9 depicts a partially assembled electronics system 913 and an assembled liquid-based cooling system 915 coupled to primary heat generating components (e.g., including processor dies) to be cooled. In this embodiment, the electronics system is configured for (or as) an electronics drawer of an electronics rack, and includes, by way of example, a support substrate or planar board 905, a plurality of memory module sockets 910 (with the memory modules (e.g., dual in-line memory modules) not shown), multiple rows of memory support modules 932 (each having coupled thereto an air-cooled heat sink 934), and multiple processor modules (not shown) disposed below the liquid-cooled cold plates 920 of the liquid-based cooling system 915.

In addition to liquid-cooled cold plates 920, liquid-based cooling system 915 includes multiple coolant-carrying tubes, including coolant supply tubes 940 and coolant return tubes 942 in fluid communication with respective liquid-cooled cold plates 920. The coolant-carrying tubes 940, 942 are also connected to a header (or manifold) subassembly 950 which facilitates distribution of liquid coolant to the coolant supply tubes and return of liquid coolant from the coolant return tubes 942. In this embodiment, the air-cooled heat sinks 934 coupled to memory support modules 932 closer to front 931 of electronics drawer 913 are shorter in height than the air-cooled heat sinks 934′ coupled to memory support modules 932 near back 933 of electronics drawer 913. This size difference is to accommodate the coolant-carrying tubes 940, 942 since, in this embodiment, the header subassembly 950 is at the front 931 of the electronics drawer and the multiple liquid-cooled cold plates 920 are in the middle of the drawer.

Liquid-based cooling system 915 comprises a preconfigured monolithic structure which includes multiple (pre-assembled) liquid-cooled cold plates 920 configured and disposed in spaced relation to engage respective heat generating electronic components. Each liquid-cooled cold plate 920 includes, in this embodiment, a liquid coolant inlet and a liquid coolant outlet, as well as an attachment subassembly (i.e., a cold plate/load arm assembly). Each attachment subassembly is employed to couple its respective liquid-cooled cold plate 920 to the associated electronic component to form the cold plate and electronic component assemblies. Alignment openings (i.e., thru-holes) are provided on the sides of the cold plate to receive alignment pins or positioning dowels during the assembly process, as described further in the above-incorporated patent application entitled “Method of Assembling a Cooling System for a Multi-Component Electronics System”. Additionally, connectors (or guide pins) are included within attachment subassembly which facilitate use of the attachment assembly.

As shown in FIG. 9, header subassembly 950 includes two liquid manifolds, i.e., a coolant supply header 952 and a coolant return header 954, which in one embodiment, are coupled together via supporting brackets. In the monolithic cooling structure of FIG. 9, the coolant supply header 952 is metallurgically bonded in fluid communication to each coolant supply tube 940, while the coolant return header 954 is metallurgically bonded in fluid communication to each coolant return tube 952. A single coolant inlet 951 and a single coolant outlet 953 extend from the header subassembly for coupling to the electronics rack's coolant supply and return manifolds (not shown).

FIG. 9 also depicts one embodiment of the preconfigured, coolant-carrying tubes. In addition to coolant supply tubes 940 and coolant return tubes 942, bridge tubes or lines 941 are provided for coupling, for example, a liquid coolant outlet of one liquid-cooled cold plate to the liquid coolant inlet of another liquid-cooled cold plate to connect in series fluid flow the cold plates, with the pair of cold plates receiving and returning liquid coolant via a respective set of coolant supply and return tubes. In one embodiment, the coolant supply tubes 940, bridge tubes 941 and coolant return tubes 942 are each preconfigured, semi-rigid tubes formed of a thermally conductive material, such as copper or aluminum, and the tubes are respectively brazed, soldered or welded in a fluid-tight manner to the header subassembly and/or the liquid-cooled cold plates. The tubes are preconfigured for a particular electronics system to facilitate installation of the monolithic structure in engaging relation with the electronics system.

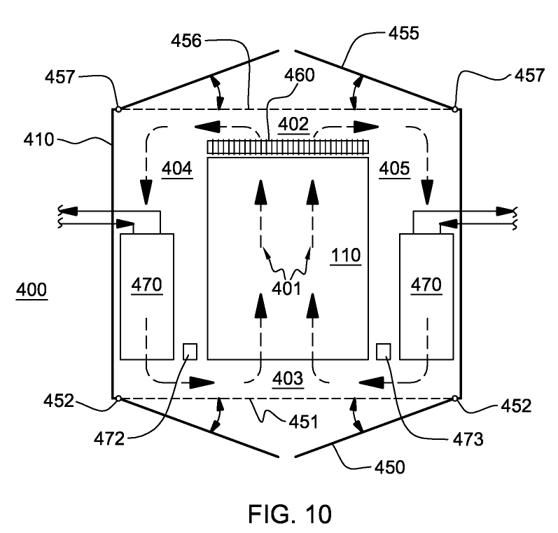

FIGS. 10 & 11 illustrate a similar docking embodiment to that illustrated in FIGS. 4 & 5. In this embodiment, the first cooling loops of the modular cooling units 470 again extend below a raised floor 140 to facilitate positioning of electronics rack 110 within the central opening of the enclosure 410. Further, modular cooling units 470 are again disposed in the side air return pathways 404, 405, and are identically-sized to facilitate establishing of a balanced closed loop airflow path 401 passing from an air inlet side to an air outlet side of the electronics rack, through at least one heat exchange assembly 460 disposed at the rear of the electronics rack, and back to the air inlet side of the rack through rear air return pathway 402, side air return pathways 404, 405, and front air return pathway 403. In this embodiment, the shared system coolant supply manifold 472 and shared system coolant return manifold 473 are disposed near a front edge of the electronics rack within the side air return pathways 404, 405. As shown, spacing is provided around the identically-sized modular cooling units 470 and the identically-sized supply/return manifolds 472, 473, to allow for balanced re-circulation of air to the air inlet side of the electronics rack.

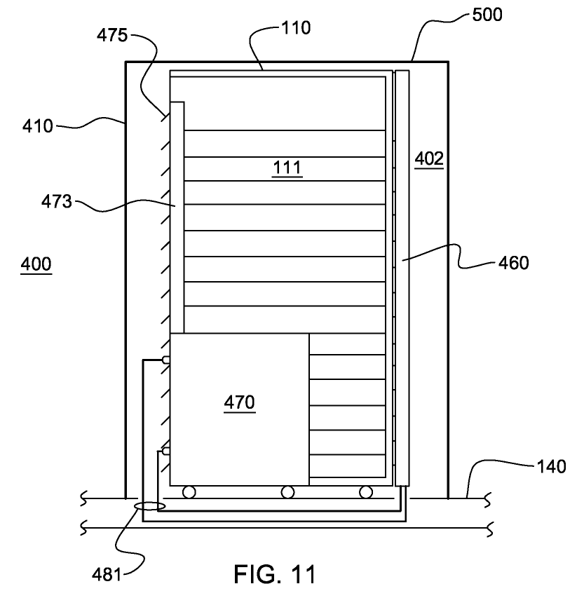

In the embodiment of FIG. 10, the front access doors are shown hinged 452 to the docking station and partially opened, exposing a front access opening 451 through which the electronics rack and modular cooling units may be positioned within the docking station. Further, rear doors 455 are hinged 457 to the docking station and partially opened to expose a rear access opening 456 to allow access to the air-to-liquid heat exchange assembly 460 and/or air outlet side of the electronics rack. In one embodiment, the air-to-liquid heat exchange assembly 460 extends substantially the entire height of electronics rack 110, as illustrated in FIG. 11, so that all air egressing from the electronics rack passes through the heat exchanger.

In FIG. 11, cover 500 is shown. This cover functions with the at least one side wall of enclosure 410 to define a substantially air-tight seal about the electronics rack, so that substantially all cooling of the electronics components operating within the docking station occurs via the hybrid air and liquid cooling of the docking station. Relative sizing of modular cooling unit 470 is also illustrated in FIG. 11. As shown, modular cooling unit 470 is, in one embodiment, less than half the height of electronics rack 110. Also shown in FIG. 11 are system coolant lines of the second cooling loop 481 of modular cooling unit 470, as well as the shared system coolant return manifold 473 and flexible tubes 475 coupling the manifold to the individual electronics subsystems 111 within electronics rack 110.

In one embodiment, the air-to-liquid heat exchange assembly is again hingedly mounted within the docking station to pivot and allow access to the air outlet side of the electronics rack when the rack is operatively disposed within the docking station.

Advantageously, the hybrid docking station disclosed herein facilitates enhanced, and customized, control of cooling of individual electronics racks within a data center. Depending on the amount of heat generated by electronics components within a given rack, the temperature of the system coolant flowing within the corresponding docking station can be adjusted, for example, by directing more or less facility coolant through the respective liquid-to-liquid heat exchangers of the modular cooling units disposed therein. Further, the hybrid docking station disclosed herein can be sized to accept various-sized electronics racks with different heat loads and air flow requirements. Additionally, the facility coolant lines, and system coolant lines, may be hard-plumbed in a hybrid docking station such as presented herein for use with refrigerant coolants. Enhanced acoustic mitigation is also achieved employing the hybrid docking station presented, which can be particularly advantageous for future electronics racks where air flow rates could be 4000 CFM, or greater.

Although preferred embodiments have been depicted and described in detail herein, it will be apparent to those skilled in the relevant art that various modifications, additions, substitutions and the like can be made without departing from the spirit of the invention and these are therefore considered to be within the scope of the invention as defined in the following claims.

What is claimed is:

1. A docking station for facilitating cooling of an electronics rack, the docking station comprising:
an enclosure comprising at least one wall, a cover coupled to the at least one wall, and a central opening sized to receive an electronics rack therein through an access opening in the at least one wall, the enclosure being separate and freestanding from the electronics rack, and the electronics rack comprising an air inlet side and an air outlet side, the air inlet and air outlet sides of the electronics rack respectively enabling ingress and egress of air, and wherein when the electronics rack is operatively positioned within the central opening, the enclosure surrounds the electronics rack and facilitates establishing a closed loop airflow path therein passing through the air inlet and air outlet sides of the electronics rack and through at least one air return pathway of the enclosure;
at least one air-to-liquid heat exchange assembly disposed within the at least one air return pathway of the enclosure for cooling air circulating through the closed loop airflow path; and
at least one modular cooling unit disposed within the enclosure, the at least one modular cooling unit providing system coolant to the at least one air-to-liquid heat exchange assembly and to at least one electronics subsystem of the electronics rack to be cooled, each modular cooling unit comprising a liquid-to-liquid heat exchanger, a first cooling loop, and a second cooling loop, the first cooling loop receiving chilled facility coolant from a source and passing at least a portion thereof through the liquid-to-liquid heat exchanger, the second cooling loop providing cooled system coolant to the at least one air-to-liquid heat exchange assembly and to the at least one electronics subsystem, and expelling heat in the liquid-to-liquid heat exchanger from the at least one air-to-liquid heat exchange assembly and from the at least one electronics subsystem to the chilled facility coolant in the first cooling loop.

2. The docking station of claim 1, further comprising a shared system coolant supply manifold and a shared system coolant return manifold, the shared system coolant supply manifold and the shared system coolant return manifold being disposed within the second cooling loop of each modular cooling unit of the at least one modular cooling unit.

3. The docking station of claim 2, further comprising multiple modular cooling units disposed within the enclosure, the multiple modular cooling units each providing cooled system coolant to the at least one air-to-liquid heat exchange assembly and to the shared system coolant supply manifold for distribution to the at least one electronics subsystem, and each receiving exhausted system coolant from the at least one air-to-liquid heat exchange assembly and from the at least one electronics subsystem, via the shared system coolant return manifold.

4. The docking station of claim 3, wherein the shared system coolant supply manifold and the shared system coolant return manifold each extend vertically within the enclosure, and are each disposed adjacent to at least one of the air inlet side or air outlet side of the electronics rack when the electronics rack is operatively positioned within the central opening of the enclosure.

5. The docking station of claim 1, wherein the at least one return pathway comprises a first side air return pathway and a second side air return pathway disposed on opposing sides of the electronics rack when operatively positioned within the central opening of the enclosure, and wherein the docking station further comprises a first modular cooling unit and a second modular cooling unit disposed within the enclosure, the first modular cooling unit being disposed within the first side air return pathway and the second modular cooling unit being disposed within the second side air return pathway, and wherein the first modular cooling unit and the second modular cooling unit are identically sized to facilitate balanced air flow return within the enclosure through the first side air return pathway and the second side air return pathway.

6. The docking station of claim 5, wherein the at least one air-to-liquid heat exchange assembly comprises a back air-to-liquid heat exchange assembly hingedly connected within the enclosure to allow access to the air outlet side of the electronics rack and sized to cover the air outlet side of the electronics rack to cool, when operational, substantially all air egressing from the electronics rack.

7. The docking station of claim 5, wherein the identically-sized first and second modular cooling units and the enclosure are sized to allow air flowing through the first side air return pathway and the second side air return pathway to pass along at least one side of and over the first and second modular cooling units as the air re-circulates to the air inlet side of the electronics rack.

8. A data center comprising:
at least one electronics rack, each electronics rack comprising an air inlet side and an air outlet side, the air inlet and air outlet sides respectively enabling ingress and egress of air through the electronics rack; and
at least one docking station, each docking station comprising:
an enclosure comprising at least one wall, a cover coupled to the at least one wall and a central opening sized to receive a respective electronics rack therein through an access opening in the at least one wall, the enclosure being separate and freestanding from the electronics rack, wherein the enclosure surrounds the electronics rack and facilitates establishing a closed loop airflow path therein passing through the air inlet and air outlet sides of the electronics rack, and through at least one air return pathway of the enclosure;
at least one air-to-liquid heat exchange assembly disposed within the at least one air return pathway of the enclosure for cooling air circulating through the closed loop airflow path; and
at least one modular cooling unit disposed within the enclosure, the at least one modular cooling unit providing system coolant to the at least one air-to-liquid heat exchange assembly and to at least one electronics subsystem of the electronics rack to be cooled, each modular cooling unit comprising a liquid-to-liquid heat exchanger, a first cooling loop, and a second cooling loop, the first cooling loop receiving chilled facility coolant from a source and passing at least a portion thereof through the liquid-to-liquid heat exchanger, the second cooling loop providing cooled system coolant to the at least one air-to-liquid heat exchange assembly and to the at least one electronics subsystem, and expelling heat in the liquid-to-liquid heat exchanger from the at least one air-to-liquid heat exchange assembly and from the at least one electronics subsystem to the chilled facility coolant in the first cooling loop.

9. The data center of claim 8, wherein each docking station further comprises a shared system coolant supply manifold and a shared system coolant return manifold, the shared system coolant supply manifold and the shared system coolant return manifold being disposed within the second cooling loop of each modular cooling unit of the at least one modular cooling unit of the docking station.

10. The data center of claim 9, wherein each docking station further comprises multiple modular cooling units disposed within the enclosure, the multiple modular cooling units each providing cooled system coolant to the at least one air-to-liquid heat exchange assembly and to the shared system coolant supply manifold for distribution to the at least one electronics subsystem, and each receiving exhausted system coolant from the at least one air-to-liquid heat exchange assembly and from the at least one electronics subsystem, via the shared system coolant return manifold.

11. The data center of claim 10, wherein the shared system coolant supply manifold and the shared system coolant return manifold of each docking station extend vertically within the enclosure thereof, and are disposed adjacent to at least one of the air inlet side or air outlet side of the electronics rack when the electronics rack is operatively positioned within the central opening of the enclosure.

12. The data center of claim 8, wherein the at least one return pathway of each docking station comprises a first side air return pathway and a second side air return pathway disposed on opposing sides of the electronics rack, and wherein each docking station further comprises a first modular cooling unit and a second modular cooling unit disposed within the enclosure thereof, the first modular cooling unit being disposed within the first side air return pathway and the second modular cooling unit being disposed within the second side air return pathway, and wherein the first modular cooling unit and the second modular cooling unit are identically sized to facilitate balanced air flow return within the enclosure through the first side air return pathway and the second side air return pathway.

13. The data center of claim 12, wherein the at least one air-to-liquid heat exchange assembly of each docking station comprises a back air-to-liquid heat exchange assembly hingedly connected within the enclosure thereof to allow access to the air outlet side of the electronics rack and sized to cover the air outlet side of the electronics rack to cool, substantially all air egressing from the electronics rack.

14. The data center of claim 12, wherein within each docking station the identically-sized first and second modular cooling units and the enclosure are sized to allow air flowing through the first side air return pathway and the second side air return pathway to pass along at least one side of and over the first and second modular cooling units as the air re-circulates to the air inlet side of the electronics rack operatively disposed within the enclosure.

15. The data center of claim 8, wherein the data center comprises a plurality of electronics racks and a plurality of docking stations, each docking station having a respective electronics rack of the plurality of electronics racks disposed in operative position within the central opening thereof, and wherein the at least one modular cooling unit disposed within the enclosure of each docking station provides separate cooling control for the electronics rack disposed within that docking station.

16. A method of cooling an electronics rack, the method comprising:
providing a docking station for cooling an electronics rack, the docking station comprising:
an enclosure comprising at least one wall, a cover coupled to the at least one wall, and a central opening sized to receive the electronics rack therein through an access opening in the at least one wall, the enclosure being separate and freestanding from the electronics rack, and the electronics rack comprising an air inlet side and an air outlet side, the air inlet and air outlet sides respectively enabling ingress and egress of air;
at least one air-to-liquid heat exchange assembly disposed within at least one air return pathway of the enclosure for cooling circulating air passing therethrough;
at least one modular cooling unit disposed within the enclosure, each modular cooling unit comprising a liquid-to-liquid heat exchanger, a first cooling loop, and a second cooling loop;
disposing the electronics rack within the central opening and closing the electronics rack within the enclosure;
establishing air flow through the electronics rack employing at least one air-moving device, wherein the establishing results in a closed loop airflow path being established within the enclosure, the closed loop airflow path passing through the air inlet and air outlet sides of the electronics rack and through the at least one air return pathway of the enclosure;
providing chilled facility coolant from a source to the first cooling loop of each modular cooling unit and passing at least a portion thereof through the liquid-to-liquid heat exchanger, and pumping cooled system coolant through the second cooling loop of each modular cooling unit to the at least one air-to-liquid heat exchange assembly and to at least one electronics subsystem of the electronics rack to be cooled, wherein heat is expelled in the liquid-to-liquid heat exchanger from the at least one air-to-liquid heat exchange assembly and from the at least one electronics subsystem to the chilled facility coolant in the first cooling loop; and
employing the at least one air-to-liquid heat exchange assembly to cool air circulating within the enclosure through the closed loop airflow path, and employing the at least one modular cooling unit to cool the at least one air-to-liquid heat exchange assembly and to cool the at least one electronics subsystem of the electronics rack.

17. The method of claim 16, wherein providing the docking station further comprises providing a shared system coolant supply manifold and a shared system coolant return manifold, the shared system coolant supply manifold and the shared system coolant return manifold being disposed within the second cooling loop of each modular cooling unit of the at least one modular cooling unit of the docking station.

18. The method of claim 17, wherein providing the docking station further comprises providing multiple modular cooling units disposed within the enclosure, the multiple modular cooling units each providing cooled system coolant to the at least one air-to-liquid heat exchange assembly and to the shared system coolant supply manifold for distribution to the at least one electronics subsystem, and each receiving exhausted system coolant from the at least one air-to-liquid heat exchange assembly and from the at least one electronics subsystem, via the shared system coolant return manifold.

19. The method of claim 16, wherein providing the docking station further comprises providing the shared system coolant supply manifold and the shared system coolant return manifold to extend vertically within the enclosure and be disposed adjacent to at least one of the air inlet side or air outlet side of the electronics rack when the electronics rack is operatively positioned within the central opening of the enclosure.

20. The method of claim 16, wherein providing the docking station further comprises providing the docking station to include a first side air return pathway and a second side air return pathway disposed on opposing sides of the electronics rack positioned within the central opening of the enclosure, and wherein providing the docking station further comprises providing the docking station with a first modular cooling unit and a second modular cooling unit disposed within the enclosure, the first modular cooling unit being disposed within the first side air return pathway and the second modular cooling unit being disposed within the second side air return pathway, and wherein the first modular cooling unit and the second modular cooling unit are identically sized to facilitate balanced air flow return within the enclosure through the first side air return pathway and the second side air return pathway.
